(19) United States
(12) Patent Application Publication
(10) Pub. No.: US 2026/0370229 A1
(43) Pub. Date: Nov. 19, 2026

(54) VISUALIZING INTERNAL LOGIC STATES OF A CONFIGURABLE LOGIC BLOCK

(71) Applicant: Microchip Technology Incorporated, Chandler, AZ (US)

(72) Inventors: Attila Kolinger, Wels (AT); Bogdan Cristian Ardeleanu, Agigea (RO)

(73) Assignee: Microchip Technology Incorporated, Chandler, AZ (US)

(21) Appl. No.: 19/281,336

(22) Filed: Jul. 25, 2025

Related U.S. Application Data
(60) Provisional application No. 63/806,807, filed on May 16, 2025.

(51) Int. Cl. H03K 19/17704; G01R 31/317; G06F 11/32; H03K 19/17784

(52) U.S. Cl. CPC H03K 19/17716; G01R 31/31705; G06F 11/325; H03K 19/17784

(57) ABSTRACT

A computer-implemented method, media, and systems for setting a deallocate value for a flag within a data storage device may include: receiving, by the data storage device, a command from a host; dividing, based on the command, a range of logical block addresses corresponding to the data storage device into cache-aligned sub-ranges; determining that the sub-ranges include a full cache line; and setting, based on the command and the determination that the sub-ranges include the full cache line, the deallocate value for the flag in the full cache line.

### CROSS-REFERENCE TO RELATED APPLICATIONS

The current patent application claims the benefit under 35 U.S.C. § 119(e) of the priority date of U.S. Provisional Application Ser. No. 63/806,807, titled “VISUALLY DEBUGGING INTERNAL LOGIC STATES OF A CONFIGURABLE LOGIC BLOCK,” and filed May 16, 2025. The Provisional Application is hereby incorporated by reference, in its entirety, into the current patent application.

### TECHNICAL FIELD

Various examples of the present disclosure relate to configurable logic blocks (CLBs) and, more particularly, to a system and method of visually debugging one or more logic elements (LEs) included in a CLB.

### BACKGROUND

A CLB is a small, reconfigurable digital module, which is commonly included in field-programmable gate arrays (FPGAs). CLBs may also be integrated into a microcontroller (MCU) for performing hardware-based digital logic independent of a central processing unit (CPU). A CLB may be used to provide fast and reliable response times for a range of applications, including automotive and industrial. It is generally desirable to improve the performance and reduce the cost of CLBs, but it may be difficult to do so.

This background discussion is intended to provide related information, and is not necessarily prior art.

### SUMMARY OF THE INVENTION

According to various examples of the present disclosure, a computer-implemented method for visualizing a logic state of a logic element included in a CLB may include: receiving an electromagnetic signal corresponding to the logic state of the logic element; and outputting, via a display device, indicia of the logic state of the logic element, wherein the indicia are based on the electromagnetic signal.

In various examples, an apparatus configured to display a logic state of a logic element included in a CLB may include: circuitry configured to receive, via a single pin, an electromagnetic signal corresponding to the logic state; and an array of light-emitting diodes (LEDs) configured to alter one or more of wavelength or intensity of one or more of the individual LEDs included in the array based on the logic state.

This summary is not intended to identify essential features of the examples, and is not intended to be used to limit the scope of the claims. These and other aspects of the present examples are described below in greater detail.

### BRIEF DESCRIPTION OF THE DRAWINGS

Examples are described in detail below with reference to the attached drawing figures, wherein:

FIG. 1 is a high-level block diagram depiction of a CLB including a plurality of LEs, in accordance with the present disclosure;

FIG. 2 is an illustration of a first example system for debugging a plurality of LEs included in a CLB via a single debugging pin, in accordance with the present disclosure;

FIG. 3 is an illustration of a resistor network for debugging LEs included in a CLB, in accordance with the present disclosure;

FIG. 4 is an illustration of a waveform representing an electromagnetic signal that may be output via the single debugging pin of the CLB of FIG. 2, and visualized via a display device, in accordance with the present disclosure;

FIG. 5 is an example of a display device that may be used to visualize the logic state(s) corresponding to the electromagnetic signal corresponding to the waveform depicted in FIG. 4, in accordance with the present disclosure; and

FIG. 6 describes a method for visualizing the logic state of a LE included in a CLB, in accordance with the present disclosure.

The figures are not intended to limit the examples to the specific details depicted. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, and process changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

Terms of relative location and direction (e.g., above, below, left, right, upper, lower, vertical, horizontal, lateral, and the like) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example or this disclosure to the specified components, operations, features, functions, or the like.

It will be readily understood that the components of the examples as generally described herein and illustrated in the drawings could be arranged and designed in a wide variety of different configurations. Thus, the following description of various examples is not intended to limit the scope of the present disclosure but is merely representative of various examples Examples provide a method for visualizing a logic state of a basic LE (or simply “LE”) included in a CLB, e.g., for the purposes of debugging the logic state. Examples of basic LEs that may be debugged, and the corresponding logic states which may be visualized, include, but are not limited to: AND, OR, NOT-AND (NAND), and NOT-OR (NOR) gates; buffers and inverting buffers; D flip-flops; JK flip-flops; multiplexers; and N-input look-up tables (LUTs), where “N” is a positive integer value.

After configuration, or programming, and prior to deployment of a CLB (or a device including a CLB, such as an FPGA), the logic state(s) of at least some of the LEs included in the CLB may require debugging. For larger devices with relatively high numbers of pins, it is known to use multiple LE state outputs (e.g., FLASH FPGA), which requires multiple pins. However, for “small” devices including relatively smaller logic modules (e.g., a CLB including two hundred fifty-six (256) or fewer LEs) with a relatively smaller number of pins (e.g., eight (8) or fewer pins), it is generally desirable to use as few pins as possible for debugging processes (preferably one (1)). The present disclosure seeks to facilitate the debugging of such smaller CLBs by providing visual cues, or indicia, corresponding to the logic state(s) of the basic LEs included therein, via an array of LEDs or other suitable display device coupled to the CLB including the LE(s) that are being debugged via a single pin.

Conventionally, a combination of equipment, software-based solutions, and version control, without limitation, may be used to debug products under development. Collectively, the processes and/or techniques outlined in this paragraph may be referred to as “debugging processes.” Examples of equipment that may be used for executing debugging processes may include, but are not limited to: logic analyzers, oscilloscopes, and multimeters. Logic analyzers may be internally embedded logic analyzers (ILAs) and/or logic analyzing software that may, without limitation, be used for: inserting debug cores or other vendor-specific processes into the CLB during synthesis, probing (and analyzing) internal signals to observe behavior/operation and/or logic state(s) of LE(s) included therein in real-time, and acquiring data; triggering events (e.g., such as initializing data capture) and/or triggering a transition of logic state of one or more Les; analyzing recorded data (e.g., data transferred from an FPGA including the CLB to a computing device, such as a personal computer); and/or iterative refinement (e.g., modifying CLB design based on previously performed debugging operations). External equipment, such as externally connected logic analyzers, oscilloscopes, and multimeters may be connected to various outputs of the CLB (e.g., via a pin(s) of an FPGA including the CLB) to, without limitation: analyze, or visually represent, signals being received by, or output from, the CLB; analyze, or visually represent, internal signals (e.g., intermediate signals, or intermediate frequencies) within the CLB; and/or analyze or visually represent triggering and/or switching of logic state(s) of LE(s) included in the CLB. Software-based solutions, such as emulation, various test benches, software version control, and code review/analysis may also be used while debugging to perform and/or ensure the accuracy, or correctness, of any of the above-described debugging operations, without limitation, before physically implementing (e.g., via hardware) the CLB being developed. However, much of the equipment can be expensive and/or can take up a lot of space, while the software-based solutions can be expensive, time consuming, and/or complicated to implement and maintain.

The present disclosure seeks to introduce methods and apparatus that enable the visualization of the logic state(s) of one or more LEs included in a device that is being debugged via a display device. Various examples of the present disclosure include an array of LEDs. An array of LEDs is cheaper to produce and maintain, and simpler to connect and operate, than the conventional debugging means mentioned above. Further, according to the present disclosure, the array of LEDs can be configured in such a way that color-blind or otherwise visually impaired people can still quickly and easily visualize and interpret the indicia of the logic state(s) being displayed by the array.

While examples presented herein are primarily directed toward debugging the logic state(s) of one or more LE includes in CLBs, it will be appreciated that the techniques and devices discussed herein may be applied to other logic modules to visualize the logic state(s) of LE(s) included therein.

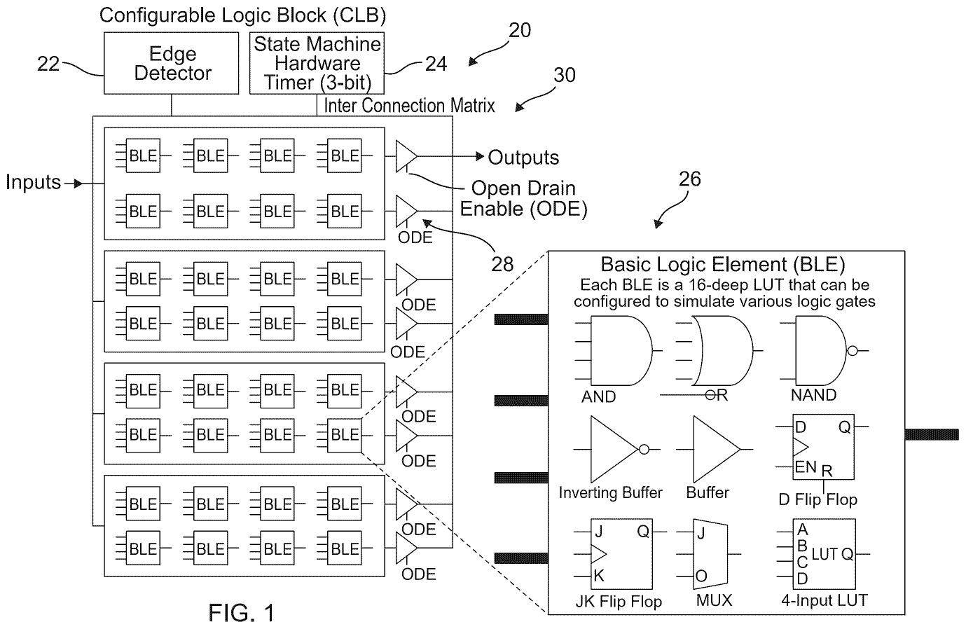

Referring to FIG. 1, a relevant portion of an example CLB 20 or other small logic module is illustrated. The CLB 20 may, in various example operating environments, be included in an FPGA. Various circuitry, including an edge detector 22, a state machine hardware timer 24, a plurality of basic LEs 26, a plurality of buffers 28, and an interconnection matrix 30, may be included in, or communicatively coupled to, the CLB 20.

The edge detector 22 may be configured to detect a rising or a falling edge of an input signal (e.g., the “Inputs” seen on the left-hand edge of the CLB 20 in FIG. 1). Edge detection may include generating an interrupt in a MCU when a rising/falling edge is detected, transitioning between different logic states when an edge is detected, and marking the timing of an event when an edge is detected. The state machine hardware timer 24 may be configured to count up or down to a set value. Various events, such as an interrupt, may be triggered by the state machine hardware timer 24 based on set threshold and/or timing values.

The plurality of LEs 26 may be arranged in an array and may be selectively connectable during programming of the CLB 20 to create a desired logic circuit. In various examples, the plurality of LEs 26 may include approximately two hundred fifty-six (256) or fewer LEs, although it will be appreciated that the CLB 20 may include fewer or more than two hundred fifty-six (256) LEs without departing from spirit of the present disclosure.

Typically, the plurality of LEs 26 may include some or all of AND, OR, NAND, and NOR gates; buffers and inverting buffers; D flip-flops; JK flip-flops; multiplexers; and four-input look-up tables (LUTs). The plurality of buffers 28 may be configured to store intermediate or final output signals from some or all of the LEs before the signals are sent on. In the illustrated example, there may be at least one buffer for each row of LEs in the CLB 20. The interconnection matrix 30 may be configured to carry signals between one or more input pins, the plurality of LEs 26, the plurality of buffers 28, and one or more output pins.

In various examples, the CLB 20 may support logic state streaming. Broadly, and within the context of testing/debugging digital circuitry, “logic state streaming” may refer to the ability of digital testing equipment (e.g., logic analyzers) to capture and stream sequences of digital logic states (typically, logic “high” and logic “low”), in real-time. This allows for the analysis of logic state(s) of the LEs included in the CLB 20 over time (e.g., to ensure the device including the CLB 20 is operating properly). According to examples of the present disclosure, the logic state of the LEs included in the CLB 20 may be one or more of: a logic high state, a logic low state, an imperceptible state, and an unavailable state.

The logic high state may correspond to a value of one (1) while the logic low state may correspond to a value of zero (0), although it will be appreciated that the logic high state corresponding to a value of zero (0) while the logic low state corresponding to a value of one (1) is within the scope of the present disclosure. The imperceptible state may correspond to a scenario in which the logic state(s) of the LE(s) being debugged/tested are changing rapidly. For example, a threshold, or standard, for a LE being in an imperceptible state may correspond to the logic state of the LE changing (e.g., switching from “high” to “low”) at a rate that is too fast for the human eye to perceive. The unavailable state may correspond to a LE and/or the output of the LE being unavailable (e.g., an output for that particular LE within a CLB may exist on the silicon wafer on which the CLB was formed, but the output was not connected to an input-output (I/O) pin on the device that includes the CLB, without limitation).

According to examples of the present disclosure, debugging may be implemented via hardware, software, or a combination thereof, and may use only a single (one (1)) pin. In various examples, a debugging environment may include, or be communicatively coupled to, hardware for debugging. The debugging hardware may alternatively be referred to as “debugging circuitry” herein.

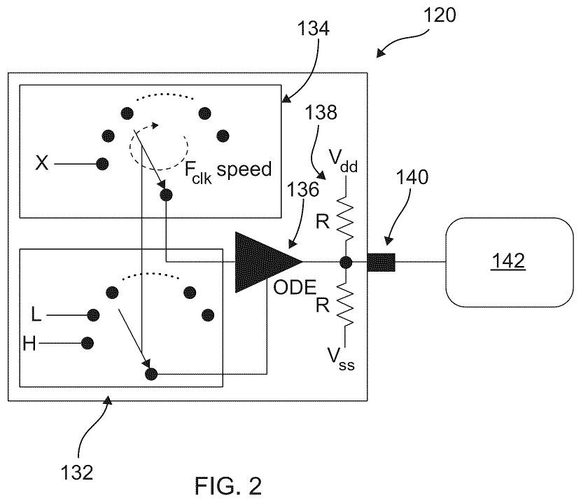

Turning particularly to FIG. 2, debugging circuitry 120 of various examples may include some or all of a synchronization pulse generator 132, a digital selector switch 134, an output buffer 136, a resistor network 138, a single debug pin 140, and a display device 142. Each LE of the plurality of LEs 26 may be associated with a particular logic state, and examples of the present disclosure facilitate visualizing the particular logic state of some or all of the LEs currently, and/or as one or more logic states change over time, to facilitate debugging to ensure that the plurality of LEs 26 have been properly selectively connected to achieve the desired circuit. Logic states, and changes thereto, may be monitored and visualized in real-time.

The synchronization pulse generator 132 may be configured to generate a synchronization, or SYNC, pulse (e.g., V_{SYNC}) prior to the debugging circuitry 120 outputting a present logic state of a first LE of the plurality of LEs, thereby indicating the beginning of a series of logic state outputs. Thus, in time multiplex, the SYNC pulse establishes “time slot zero.”

The digital selector switch 134 may be configured to connect each LE output, in turn, to the output buffer 136 for output to the debug pin 140 and visualization on the display device 142. The digital selector switch 134 may have a number of switch points equal to the number of LEs plus one (1) for the SYNC pulse. As a non-limiting example, a digital selector switch for a CLB (e.g., the CLB 20 of FIG. 1) with thirty-two (32) LEs may have thirty-three (33) switch points, while a digital selector switch for a CLB with one hundred twenty-eight (128) LEs may have one hundred twenty-nine (129) switch points. Using time multiplex to show the particular logic states of the LEs on the debug pin 140 may facilitate debugging while shortening the development cycle. The SYNC pulse may differ from the LE outputs with regard to one or more of voltage, pulse-time duration, signal frequency, or signal phase, or the SYNC pulse may be distinguished by, e.g., a clock burst that has a higher frequency than the LE timeslot.

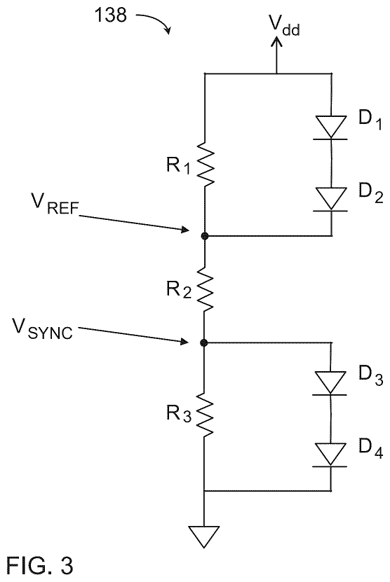

The output buffer 136 may receive and output the SYNC pulse from the synchronization pulse generator 132, and receive and output, in turn, the output from each LE from the digital selector switch 134. The resistor network 138 may be connected to the output line from the output buffer 136 to the single debug pin 140. The resistor network 138 may be configured, e.g., as a one-to-one (1:1) voltage divider with first and second resistors of the same Ohmic value, or, as depicted in FIG. 3 and explained further below, as a voltage dependent reference circuit. It will be appreciated that other topologies of a resistor network are within the scope of the present disclosure. Further, although referred to as the “resistor” network 138 above, and elsewhere throughout this specification, it will be appreciated that the resistor network 138 may include components (e.g., capacitors and/or inductors) that introduce other forms of impedance without departing from the spirit of the present disclosure.

Continuing with the description of FIG. 2, the single debug pin 140 may be an existing output pin on the CLB 20 connected to the output line of the output buffer 136, wherein the resistor network 138 is interposed between the output buffer 136 and the single debug pin 140. The single debug pin 140 may be shared with one or more other functions when it is not being used for debugging. The display device 142 may be an array of light-emitting diodes (LEDs), or other suitable display device. The display device 142 may be communicatively coupled to the debugging circuitry 120 via a single pin, such as the single debug pin 140. In various examples, the debugging circuitry 120 may include, or be communicatively coupled to, the CLB 20.

FIG. 3 depicts the resistor network 138 when configured as a voltage dependent reference circuit. At a high level, a voltage dependent reference circuit is a type of voltage reference circuit that has a variable output voltage. Typically, the output voltage of a voltage dependent reference circuit varies based on a control voltage applied to the circuit and/or a current within the circuit. The resistor network 138 may output signals that are relatively precise and stable, and the output(s) can be dynamically adjusted. As such, the resistor network 138 may be used as a benchmark for comparison in debugging.

As illustrated, a source voltage, or range of source voltages (V_{dd}), is applied to the resistor network 138. A synchronization signal/pulse (V_{SYNC}), such as the SYNC pulse from the synchronization pulse generator 132, may be applied to the node labeled “V_{SYNC}” depicted in FIG. 3. A resulting reference signal (V_{REF}) may be available at the node, again depicted in FIG. 3. In some examples, this reference signal may be used as a standard or example for a baseline or ideal signal in connection with debugging operations. In other examples, the reference signal may itself be debugged.

Frequently, CLBs, such as the CLB 20, will receive, process, and/or output “fast” signals. Broadly, a “fast” signal is a signal that transitions between voltage levels, or logic states (e.g., logic high and logic low), in a short amount of time (e.g., microseconds, nanoseconds, or even picoseconds). Generally, transitions between voltage levels/logic states that occur in a relatively short amount of time may occur at a rate that is too fast for a human to perceive. Frequently, one or more transitions between voltage level/logic state in a fast signal will not be square. Increased precision in sampling rate and/or threshold voltage may be required to accurately depict the true form (e.g., slightly rounded) of transitions between voltage level/logic states of fast signals.

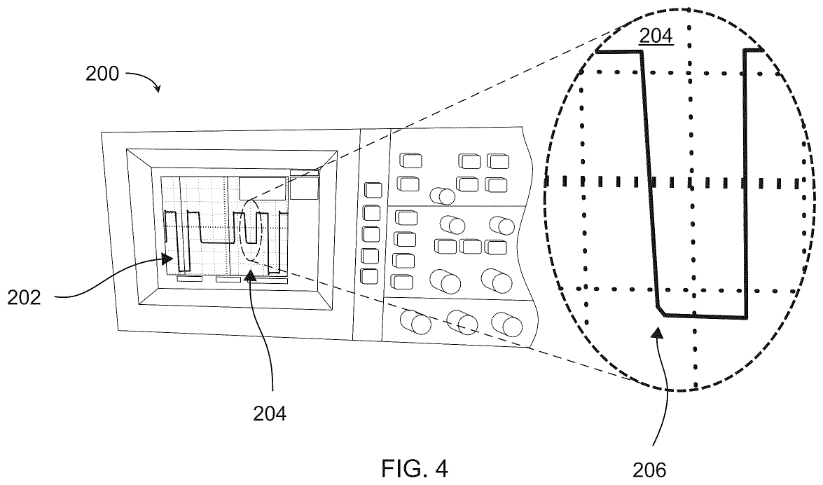

FIG. 4 illustrates an oscilloscope 200 displaying a waveform 202. The waveform 202 may be a representation of an electromagnetic signal output by the single debug pin 140 of FIG. 2. In some examples, this electromagnetic signal may be the reference signal discussed in more detail above in connection with FIG. 3. In other examples, it may be a different signal originating from circuitry communicatively coupled to, though not necessarily depicted in, FIG. 2 or 3, or mentioned elsewhere throughout this specification.

In accordance with the present disclosure, the signal output by the single debug pin 140 may be a fast signal, and may correspond to a range of voltages (e.g., the “V_{dd}” of FIG. 3) applied directly or indirectly to the CLB 20. The V_{dd} may be bounded by the particular CLB 20 and/or device incorporating the CLB 20. Also or alternatively, the V_{dd} may be bounded by the application to which the CLB 20 is put in an operational environment. In various examples, the apparatus and methods of the present disclosure are configured for debugging the full range of voltages V_{dd} for a given device or application.

As discussed above, the signal output by the single pin 140 may be a fast signal. Accordingly, one or more transitions between voltage levels/logic states represented in the waveform 202 may not be square when depicted on the oscilloscope 200. As seen in FIG. 4, a portion 204 of the waveform 202, highlighted by the dashed circle, includes one example of a transition 206 that is rounded, or otherwise not square. If a sampling rate and/or an equation used to determine a threshold voltage (e.g., a voltage level that is used by a receiving device to distinguish between logic high and logic low) for a sampled signal is too low and/or imprecise, the transition between voltage level/logic state of the received signal (e.g., the signal that is output by the single debug pin 140 and represented as waveform 202 on the oscilloscope 200) may not be accurately represented (e.g., may appear as square when it is really rounded, as transition 206 of FIG. 4 is rounded). A better level of precision may be important, particularly when using AUTOBAUD.

Broadly, AUTOBAUD may refer to a process in which a receiver automatically detects and adjusts to the data transmission speed (or baud rate) of an incoming signal (e.g., a received signal), without prior configuration or calibration specific to the source. This may be achieved by analyzing an initial, or leading, portion of the received signal to determine a correct baud rate to implement on the receiver side without manual configuration or intervention. Various pre-scaler values, register settings, and/or edge detection thresholds may be adjusted in connection with the AUTOBAUD process to ensure baud rates match.

An example of an edge detection threshold that might be adjustable during AUTOBAUD is a threshold voltage, or a voltage used to distinguish between voltage levels/logic states of the signal received signal. The logic state of a LE receiving a threshold voltage may automatically transition based on the threshold voltage. Conventionally, a threshold voltage for AUTOBAUD may be calculated via: threshold voltage=V_{dd}/2. However, due to the enhanced precision required to accurately depict the transitions between voltage levels/logic states of fast signals, a more precise equation for threshold voltage may be required. Ideally, the equation would account for the entire range of voltages (e.g., the entire range of V_{dd} applied to the resistor network of FIG. 3) that is compatible with the system, and be proportional to the voltage that is applied thereto. To achieve this level of precision, a constant (k) may be added to or subtracted from V_{dd}/2 when calculating a threshold voltage, resulting in the following, more precise equation: threshold voltage=V_{dd}/2+/−k.

For example, if the CLB 20 had a minimum Vad of one and eight-tenths (1.8) volts (V) (or V_{ddmin}=1.8V) and a maximum V_{dd} of five (5) volts (V) (or V_{ddmax}=5V), then the constant may scale with the value of V_{dd}. For instance, when operating at V_{ddmax}, the following equation may be used to calculate threshold voltage: threshold voltage=V_{dd}/2+/−1.1V, resulting in threshold voltages of 1.4V and 3.6V. When operating at V_{ddmin}, the following equation may be used to determine threshold voltage: threshold voltage=V_{dd}/2+/−0.45V, resulting in threshold voltages of 1.35V and 0.45V. Regardless of whether operating at V_{ddmax}, V_{ddmin}, or another voltage within the full range of voltages being applied to the CLB 20, the value of the constant, k, may correspond to a value of V_{dd} modified by any number of factors or equations.

As can be seen in the equations for calculating threshold voltage for an operating voltage of 5V compared to an operating voltage of 1.8V, the value of the constant, k, scales with the value of V_{dd}. It will be appreciated that the relationship between the value of V_{dd} and the value of the constant, k, may vary, e.g., based on hardware included in and/or software executing on the system (e.g., the CLB 20 and/or the example debugging circuitry 120), or based on a combination of other design specifications.

In various examples of the present disclosure, the constant, k, may equal V_{dd}/3. In these examples, the value at V_{SYNC} in FIG. 3 may equal V_{dd}/2−V_{dd}/3 while the value at V_{REF} may equal V_{dd}/2+V_{dd}/3. As before, the SYNC pulse may come from the synchronization pulse generator 132, or from circuitry external, but communicatively coupled to, the debugging circuitry 120. Similarly, the reference voltage may be supplied to, or output from, the node labeled “V_{REF}” in FIG. 3. Further, V_{REF} may be the debugged signal, the CLB 20 may be included in, or communicatively coupled to, the debugging circuitry 120, and the resistor network 138, whether configured as a voltage divider or reference circuity, may be interposed between the CLB 20 and the single output pin 140.

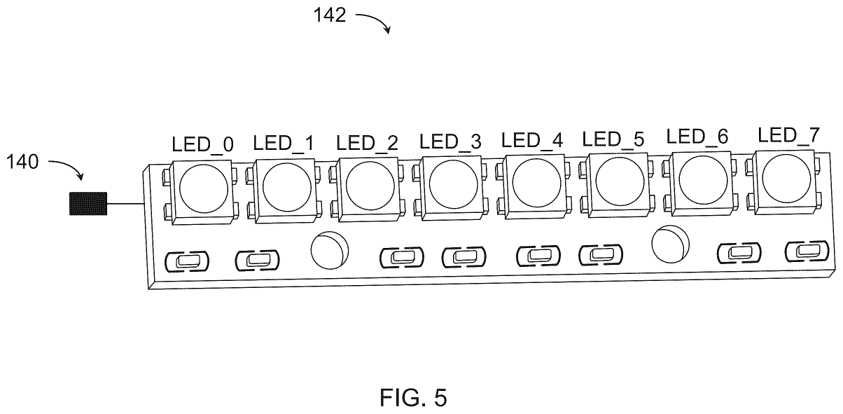

FIG. 5 illustrates an array of LEDs comprising the display device 142 connected to the output of the single debug pin 140 of FIG. 2. The array of LEDs 142 may be connected, e.g., to the CLB 20 of FIG. 1, via the single debug pin 140 to visually illustrate or emit indicia corresponding to internal logic state(s) of one or more of the LEs (e.g., one or more of the plurality of LEs 26 of FIG. 1) included in the CLB 20. Such a visual representation of the internal logic state(s) of the LEs included in a CLB may be particularly useful during debugging.

According to examples of the present disclosure, the array of LEDs 142 can emit indicia reflecting four (4) different internal logic states including: a logic high state (or “high”), a logic low state (or “low”), an imperceptible state, and an unavailable state. It may be possible for a LE to experience/be in more than one logic state at a time (e.g., the state of a particular LE may simultaneously be low and unavailable). Each of the four (4) logic states may be expressed and/or differentiated from another logic state in multiple ways via the array of LEDs 142. For instance, wavelength (e.g., color) and intensity (e.g., brightness) of light emitted from particular LEDs included in the array of LEDs 142 may be modulated to express/differentiate between the logic states.

The array of LEDs 142 includes eight (8) individual LEDs. Some or all of these eight (8) individual LEDs may be red, green, blue (RGB) LEDs. Each individual LED included in the array of LEDs 142 may be connected to the single debugging pin 140 of the CLB 20. The individual LEDs comprising the array of LEDs 142 may be designated zero (0) through seven (7). The basic LEs included in the CLB may also be numbered zero (0) through seven (7). As such, the state of the first basic LE (e.g., LE_0) may be displayed on the first LED of the array of LEDs (e.g., LED_0), the state of the second basic LE (e.g., LE_1) may be displayed on the second LED of the array of LEDs (e.g., LED_1), etc.

Some non-limiting examples of indicia corresponding to the internal logic state(s) of the LE(s) corresponding an individual LED of the array of LEDs 142 are described in this paragraph. For instance, an individual LED (e.g., LED_2 included in the array of LEDs 142) may be brightly illuminated to indicate that the corresponding basic LE is “high.” Similarly, an individual LED (e.g., LED_1 of the array of LEDs 142) may be dimly illuminated to indicate that the corresponding basic LE is “low.” An individual LED (e.g., LED_7 of the array of LEDs 142) may be turned off to indicate that the corresponding basic LE is unavailable. An individual LED flashing on and off may indicate that the corresponding LED is in an imperceptible state, e.g., a constantly changing state at a rate that cannot be perceived by humans.

Also or alternatively, for example if intensity (brightness) of light emitted from the LEDs included in the array of LEDs is unable to be modified, the wavelength (or color) of the light emitted by the LED(s) may be modified. For instance, a LE in a “high” state may cause the corresponding LED to shine yellow while a LE in a “low” state may cause the corresponding LED to shine blue. In this example, an LED shining green (e.g., the combination of blue and yellow) may indicate that the corresponding basic LE is unavailable, and an LED alternating between flashing yellow and flashing blue may indicate that the corresponding basic LE is in an imperceptible state.

If the LEDs included in the LED array support changes to wavelength and intensity, then a combination of wavelength and intensity may be relied on to indicate the state of a corresponding basic LE. It will be appreciated that other modulations/manipulations of light emitted from the LEDs included in the array of LEDs 142 (e.g., using different colors, intensities, strobe patterns, and the like, without limitation) to represent the logic state(s) of the corresponding LE(s) are permissible under the present disclosure.

As mentioned above, the LEDs included in the array of LEDs may be red, blue, green (RGB) LEDs. However, it will be appreciated that inclusion of various other types of LEDs in the array of LEDs in lieu of, or in combination with, RGB LEDs is within the scope of the present disclosure. In various examples, a hardware description language (HDL), or other suitable programming language, may be used to establish a set of instructions. The set of instructions may be stored or otherwise embodied on one or more computer-readable medium(s) communicatively coupled to the CLB. When executed by one or more processors communicatively coupled to the CLB, the instructions may govern the configuration/operation of the CLB thereby, in various examples, directly controlling the indicia displayed by the array of LEDs, or whatever other suitable display device is coupled to the single debug pin.

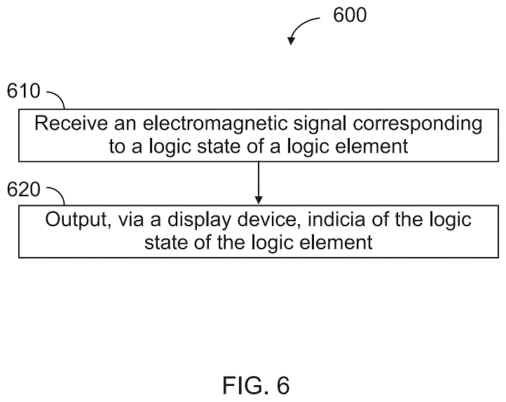

FIG. 6 illustrates a method 600 for visualizing a logic state (e.g., logic high, logic low, imperceptible, or unavailable) of a logic element (e.g., one of the plurality of LEs 26 of FIG. 1) included in a configurable logic block (e.g., the CLB 20 of FIG. 1).

The operations comprising the method 600 may be performed in the order shown in FIG. 6, or they may be performed in a different order. Further, some operations may be performed concurrently as opposed to sequentially, and some operations may be optional.

One or more computer-readable medium(s) may also be provided. The computer-readable medium(s) may include one or more executable programs stored thereon, such as firmware programs, wherein the program(s) instruct one or more processing elements to perform all or certain of the steps or operations outlined herein. The program(s) stored on the computer-readable medium(s) may instruct the processing element(s) to perform additional, fewer, or alternative actions, including those discussed elsewhere herein.

At operation 610, an electromagnetic signal corresponding to a logic state(s) of a logic element(s) included in a CLB is received. According to examples of the present disclosure, the electromagnetic signal may be output from the single debug pin 140 of FIG. 2, and originate from the debugging circuitry 120 (which may include the CLB 20), or circuitry communicatively coupled to the debugging circuitry 120 (which, again, may include the CLB 20). The electromagnetic signal may be represented by a wave form, such as the wave form 202 of FIG. 4. As such, the electromagnetic signal may be a voltage, or a range of voltages.

At operation 620, indicia of the logic state(s) of the logic element(s) included in the CLB may be output via a display device (e.g., the array of LEDs 142 of FIG. 5). The indicia may be based on, or otherwise correspond to, the electromagnetic signal from the CLB 20. For example, the rising and falling edges of the waveform 202 may be indicia of a change in voltage level corresponding to a change in logic state of one or more of the LEs 26 included in the CLB 20. As explained above, because the signals that are the subject of the present disclosure may be fast signals, the transitions may not be perfectly square. Transition 206 in highlighted portion 204 of waveform 202 of FIG. 4 may be, e.g., slightly rounded rather than square.

Additional details for each of the method operations/processes depicted in FIG. 6 can be found in the description of FIGS. 1-5 above.

Additional processing in/for each of above-mentioned method operations/processes may be performed, as desired.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

### Feature Combinations

According to various examples of the present disclosure, computer-implemented methods for visualizing a logic state of a logic element included in a configurable logic block may include: receiving an electromagnetic signal corresponding to the logic state of the logic element; and outputting, via a display device, indicia of the logic state of the logic element, wherein the indicia are based on the electromagnetic signal.

In combination with any of the previous examples, the logic state of the logic element may be one or more of: a logic high state, a logic low state, an imperceptible state, and an unavailable state.

In combination with any of the previous examples, the configurable logic block may support logic state streaming.

In combination with any of the previous examples, the configurable logic block may be included in a field-programmable gate array.

In combination with any of the previous examples, the configurable logic block may include two hundred fifty-six (256) logic elements or fewer.

In combination with any of the previous examples, the display device may include an array of light-emitting diodes (LEDs).

In combination with any of the previous examples, the indicia may be displayed via an array of LEDs and correspond to one or both of a wavelength or an intensity of light emitted from the array of LEDs.

In combination with any of the previous examples, the electromagnetic signal may be transmitted via circuitry communicatively coupled to the display device, further comprising performing debugging operations on the circuitry, the electromagnetic signal resulting from the performance of the debugging operations.

In combination with any of the previous examples, the circuitry may include, or be communicatively coupled to: a digital selector switch that includes a number of switch points equal to the number of logic elements included in the configurable logic block plus one (1); and a voltage dependent reference circuit.

In combination with any of the previous examples, the electromagnetic signal may propagate through circuitry communicatively coupled to the display device via a single pin.

In combination with any of the previous examples, the electromagnetic signal may propagate through circuitry communicatively coupled to the display device, and the circuitry may include, or be communicatively coupled to, the configurable logic block.

In combination with any of the previous examples, the electromagnetic signal may correspond to a range of source voltages applied to the configurable logic block.

In combination with any of the previous examples, the logic state of the logic element included in the configurable logic block may automatically transition when a value of a voltage affecting the circuitry equals half (½) the value of a source voltage (Vdd) included in a range of source voltages applied to the configurable logic block plus or minus a constant (k).

In combination with any of the previous examples, a constant (k) may equal Vdd/3.

In combination with any of the previous examples, a voltage affecting the circuitry may be one of a reference voltage or a synchronization voltage.

According to various examples of the present disclosure, an apparatus configured to display a logic state of a logic element included in a configurable logic block may include: circuitry configured to receive, via a single pin, an electromagnetic signal corresponding to the logic state; and an array of light-emitting diodes (LEDs) configured to alter one or more of wavelength of intensity of one or more of the individual LEDs included in the array based on the logic state.

In combination with any of the previous examples, alteration of the array of LEDs may be configured to generate indicia displayed via the array of LEDs, the indicia corresponding to the logic element being in one or more of the following logic states: a logic high state, a logic low state, an imperceptible state, and an unavailable state.

In combination with any of the previous examples, the logic state of each logic element included in the configurable logic block may be represented by a single red, green, blue (RGB) LED.

In combination with any of the previous examples, the array of LEDs may display the logic state of the corresponding logic element over a range of source voltages applied to the configurable logic block.

In combination with any of the previous examples, alteration of the array of LEDs may be configured to display indicia corresponding to the logic state of the logic element by automatically transitioning at voltages corresponding to half of a source voltage of the range of source voltages, plus or minus a constant.

### General Considerations

In this description, references to “one embodiment”, “an embodiment”, “embodiments”, “an example”, “one example”, or “examples” mean that the feature or features being referred to are included in at least one embodiment or example of the technology. Separate references to “one embodiment”, “an embodiment”, “embodiments”, “an example”, “one example”, or “examples” in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated and/or readily apparent to those skilled in the art from the description.

Certain embodiments are described herein as including logic or a number of routines, subroutines, applications, or instructions. These may constitute either software (e.g., code embodied on a machine-readable medium or in a transmission signal) or hardware. In hardware, the routines, etc., are tangible units capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as computer hardware that operates to perform certain operations as described herein.

In various embodiments, computer hardware, such as a processing element, may be implemented as special purpose or as general purpose. For example, the processing element may comprise dedicated circuitry or logic that is permanently configured, such as an application-specific integrated circuit (ASIC), or indefinitely configured, such as an FPGA, to perform certain operations. The processing element may also comprise programmable logic or circuitry (e.g., as encompassed within a general-purpose processor or other programmable processor) that is temporarily configured by software to perform certain operations. It will be appreciated that the decision to implement the processing element as special purpose, in dedicated and permanently configured circuitry, or as general purpose (e.g., configured by software) may be driven by cost and time considerations.

Accordingly, the term “processing element” or equivalents should be understood to encompass a tangible entity, be that an entity that is physically constructed, permanently configured (e.g., hardwired), or temporarily configured (e.g., programmed) to operate in a certain manner or to perform certain operations described herein. Considering embodiments in which the processing element is temporarily configured (e.g., programmed), each of the processing elements need not be configured or instantiated at any one instance in time. For example, where the processing element comprises a general-purpose processor configured using software, the general-purpose processor may be configured as respective different processing elements at different times. Software may accordingly configure the processing element to constitute a particular hardware configuration at one instance of time and to constitute a different hardware configuration at a different instance of time.

Computer hardware components, such as communication elements, memory elements, processing elements, and the like, may provide information to, and receive information from, other computer hardware components. Accordingly, the described computer hardware components may be regarded as being communicatively coupled. Where multiple of such computer hardware components exist contemporaneously, communications may be achieved through signal transmission (e.g., over appropriate circuits and buses) that connect the computer hardware components. In embodiments in which multiple computer hardware components are configured or instantiated at different times, communications between such computer hardware components may be achieved, for example, through the storage and retrieval of information in memory structures to which the multiple computer hardware components have access. For example, one computer hardware component may perform an operation and store the output of that operation in a memory device to which it is communicatively coupled. A further computer hardware component may then, at a later time, access the memory device to retrieve and process the stored output. Computer hardware components may also initiate communications with input or output devices, and may operate on a resource (e.g., a collection of information).

The various operations of example methods described herein may be performed, at least partially, by one or more processing elements that are temporarily configured (e.g., by software) or permanently configured to perform the relevant operations. Whether temporarily or permanently configured, such processing elements may constitute processing element-implemented modules that operate to perform one or more operations or functions. The modules referred to herein may, in some example embodiments, comprise processing element-implemented modules.

Similarly, the methods or routines described herein may be at least partially processing element-implemented. For example, at least some of the operations of a method may be performed by one or more processing elements or processing element-implemented hardware modules. The performance of certain of the operations may be distributed among the one or more processing elements, not only residing within a single machine, but deployed across a number of machines. In some example embodiments, the processing elements may be located in a single location (e.g., within a home environment, an office environment or as a server farm), while in other embodiments the processing elements may be distributed across a number of locations.

Unless specifically stated otherwise, discussions herein using words such as “processing,” “computing,” “calculating,” “determining,” “presenting,” “displaying,” or the like may refer to actions or processes of a machine (e.g., a computer with a processing element and other computer hardware components) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112(f) unless traditional means-plus-function language is expressly recited, such as “means for” or “step for” language being explicitly recited in the claim(s).

Although the invention has been described with reference to the embodiments illustrated in the attached drawing figures, it is noted that equivalents may be employed and substitutions made herein without departing from the scope of the invention as recited in the claims.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

What is claimed is:

1. A method for visualizing a logic state of a logic element included in a configurable logic block, the method comprising:
receiving an electromagnetic signal corresponding to the logic state of the logic element; and
outputting, via a display device, indicia of the logic state of the logic element, wherein the indicia are based on the electromagnetic signal.

2. The method of claim 1, wherein the logic state of the logic element is one or more of: a logic high state, a logic low state, an imperceptible state, and an unavailable state.

3. The method of claim 1, wherein the configurable logic block supports logic state streaming.

4. The method of claim 1, wherein the configurable logic block is included in a field-programmable gate array.

5. The method of claim 1, wherein the configurable logic block includes two hundred fifty-six (256) logic elements or fewer.

6. The method of claim 1, wherein the display device comprises an array of light-emitting diodes (LEDs).

7. The method of claim 6, wherein the indicia are displayed via the array of LEDs and correspond to one or both of a wavelength or an intensity of light emitted from the array of LEDs.

8. The method of claim 1, wherein the electromagnetic signal is transmitted via circuitry communicatively coupled to the display device, further comprising performing debugging operations on the circuitry, the electromagnetic signal resulting from the performance of the debugging operations.

9. The method of claim 8, wherein the circuitry includes, or is communicatively coupled to:
a digital selector switch that includes a number of switch points equal to the number of logic elements included in the configurable logic block plus one (1); and
a voltage dependent reference circuit.

10. The method of claim 9, wherein the circuitry is communicatively coupled to the display device via a single pin.

11. The method of claim 10, wherein the circuitry includes, or is communicatively coupled to, the configurable logic block.

12. The method of claim 9, wherein the electromagnetic signal corresponds to a range of source voltages applied to the configurable logic block.

13. The method of claim 12, wherein the logic state of the logic element included in the configurable logic block automatically transitions when a value of a voltage affecting the circuitry equals half (½) the value of a source voltage (Vdd) included in the range of source voltages plus or minus a constant (k).

14. The method of claim 13, wherein the constant (k) equals to Vdd/3.

15. The method of claim 13, wherein the voltage affecting the circuitry is one of a reference voltage or a synchronization voltage.

16. An apparatus configured to display a logic state of a logic element included in a configurable logic block, the apparatus comprising:
circuitry configured to receive, via a single pin, an electromagnetic signal corresponding to the logic state; and
an array of light-emitting diodes (LEDs) configured to alter one or more of wavelength or intensity of one or more of the individual LEDs included in the array based on the logic state.

17. The apparatus of claim 16, wherein the alteration of the array of LEDs is configured to generate indicia displayed via the array of LEDs, the indicia corresponding to the logic element being in one or more of the following logic states: a logic high state, a logic low state, an imperceptible state, and an unavailable state.

18. The apparatus of claim 16, wherein the logic state of each logic element included in the configurable logic block is represented by a single red, green, blue (RGB) LED.

19. The apparatus of claim 16, wherein the array of LEDs displays the logic state of the corresponding logic element over a range of source voltages applied to the configurable logic block.

20. The apparatus of claim 19, wherein the alteration of the array of LEDs is configured to display indicia corresponding to the logic state of the logic element by automatically transitioning at voltages corresponding to half of a source voltage of the range of source voltages, plus or minus a constant.
